(19) United States
(12) Patent Application Publication
(10) Pub. No.: US 2003/0199127 A1
(43) Pub. Date: Oct. 23, 2003

(54) Method of forming a thin film transistor on a plastic sheet

(76) Inventors: Tsung-Neng Liao, Taichung Hsien (TW); Chich Shang Chang, Taoyuan (TW); Yuan-Tung Dai, Taoyuan (TW)

Correspondence Address: BIRCH STEWART KOLASCH & BIRCH, PO BOX 747, FALLS CHURCH, VA, 22040-0747, US

(21) Appl. No.: 10/397,237

(22) Filed: Mar. 27, 2003

(30) Foreign Application Priority Data
Apr. 18, 2002 (TW) 091107975

(51) Int. Cl. H01L 21/00; H01L 21/84

(52) U.S. Cl. 438/149; 438/164

(57) ABSTRACT

A method of forming a thin film transistor (TFT) on a plastic sheet. An etching stop layer is formed on a glass substrate. A buffer layer is formed on the etching stop layer. At least one TFT structure is formed on part of the buffer layer. A passivation layer is formed on the TFT structure and the buffer layer. A plastic layer is formed on the passivation layer. The glass substrate and the etching stop layer are removed. Thus, the invention can transfer the TFT structure from the glass plate to the plastic sheet without damage from the process temperature of the TFT.

### BACKGROUND OF THE INVENTION

1. Field of the Invention

The present invention relates to a plastic display process, and more particularly, to a method of forming a thin film transistor (TFT) on a plastic sheet.

2. Description of the Related Art

Liquid crystal displays (LCDs) have been used for several years now as an information display in, e.g. calculators, watches, video games, audio and video equipment, portable computers, car dashboards, and others, especially in mobile devices wherein low weight is an important feature.

The substrates used in such devices are typically glass plates having a thickness from 0.7 to 1.1 mm. Due to the high specific weight of glass, the total weight of a display is mainly determined by the size and thickness of these glass plates. The glass plates are rigid, which hinders the LCDs from achieving flexibility. Therefore, it is important to investigate a light and flexible material for the substrates.

For some applications, plastic sheets are being used as a low-weight substrate of a LCD. The high strength and flexibility of plastics enables the making of a flexible display. However, during the high temperature process of an active device such as a thin film transistor (TFT) directly forming on the plastic sheet, the plastic sheet will have dimensional stability and an etching resistance problems. Moreover, the cutting process of the plastic sheet is more difficult than for the glass plate.

Thus, a method of forming a TFT on a plastic sheet solving the aforementioned problems is called for.

### SUMMARY OF THE INVENTION

The object of the present invention is to provide a method of forming a thin film transistor (TFT) on a plastic sheet.

Another object of the present invention is to provide a method of transferring a TFT structure from a glass plate to a plastic sheet without damage from the process temperature of the TFT.

To achieve these objects, the present invention provides a method of forming a TFT on a plastic sheet. An etching stop layer is formed on the glass substrate. A buffer layer is formed on the etching stop layer. At least one TFT structure is formed on part of the buffer layer. A passivation layer is formed on the TFT structure and the buffer layer. A plastic layer is formed on the passivation layer. The glass substrate and the etching stop layer are removed.

The present invention improves on the prior art in that the present method transfers at least one TFT structure from the glass plate to a plastic sheet without damage from the process temperature of the TFT in the manufacturing process. Thus, the invention is suitable for the fabrication of plastic displays.

### BRIEF DESCRIPTION OF THE DRAWINGS

The present invention can be more fully understood by reading the subsequent detailed description in conjunction with the examples and references made to the accompanying drawings, wherein:

FIGS. 1˜8 are schematic diagrams according to an embodiment of the present invention.

### DETAILED DESCRIPTION OF THE INVENTION

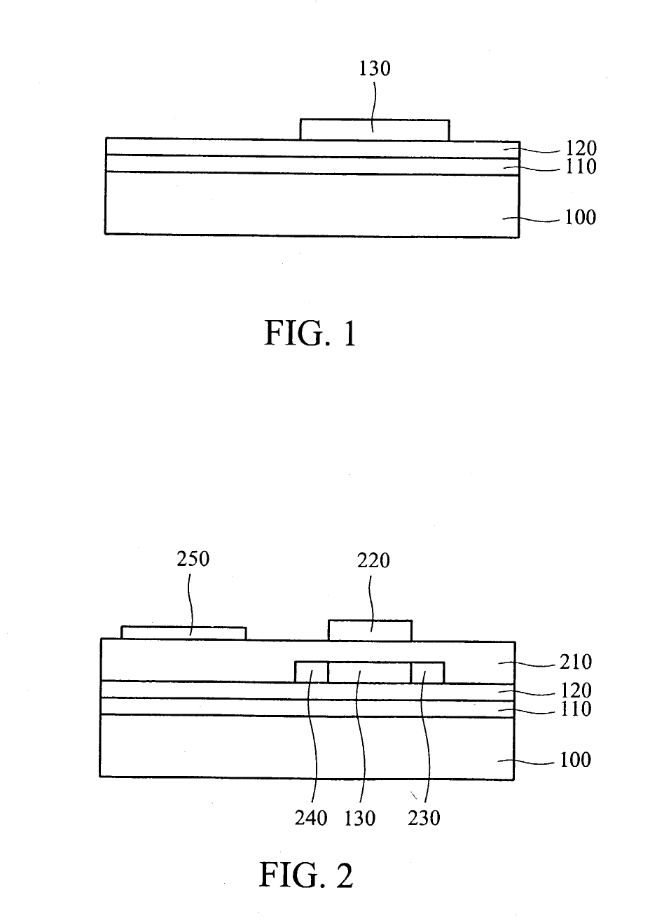

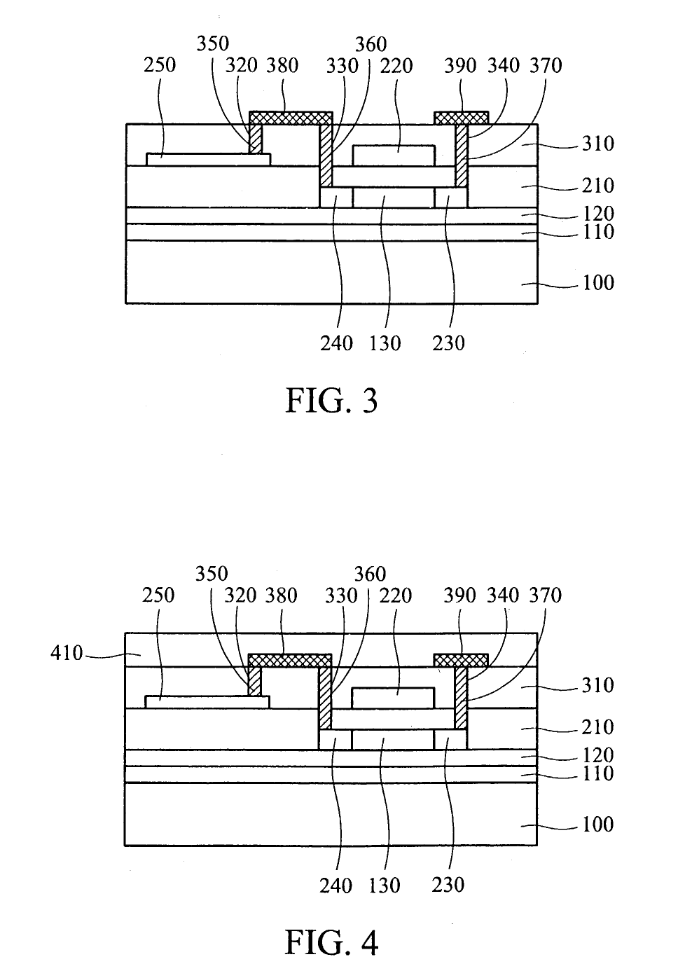

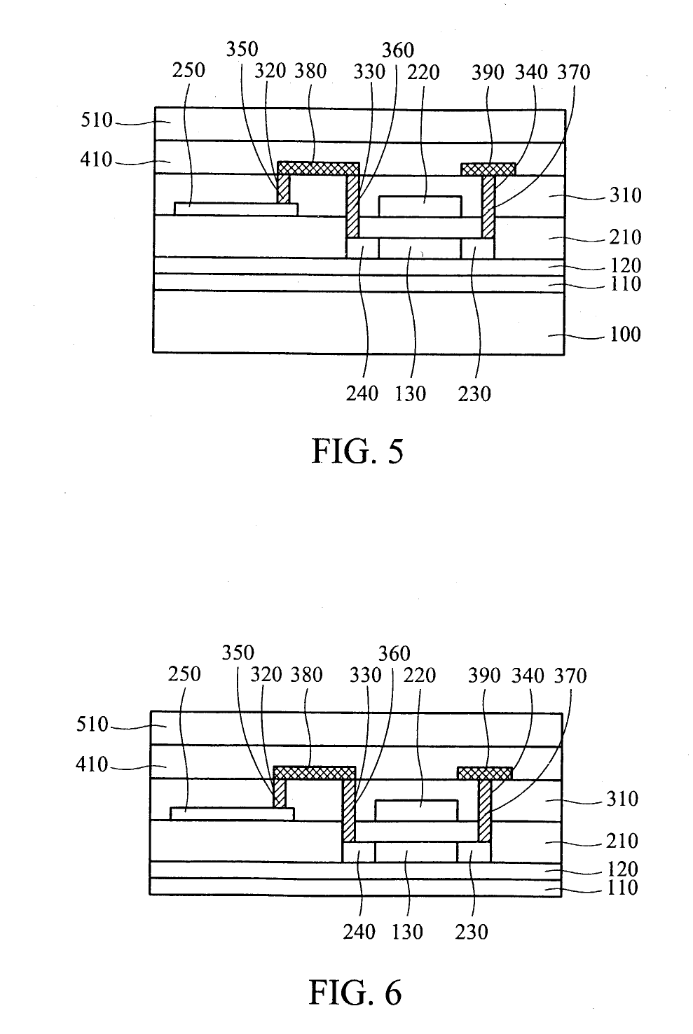

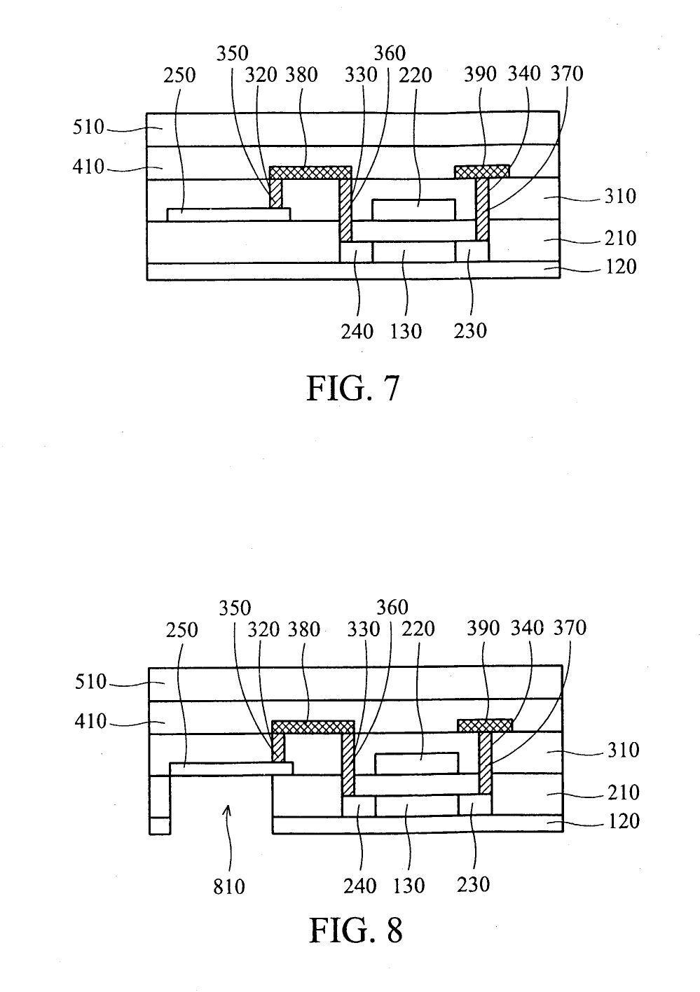

The present invention provides a method of forming at least one thin film transistor (TFT) on a heat-sensitive layer such as a plastic sheet. FIGS. 1˜8 are schematic diagrams of an embodiment of the present invention.

In FIG. 1, an etching stop layer 110 is formed on a glass substrate 100. Preferably, the glass substrate 100 is a heat-resistant glass plate. The etching stop layer 110 can be a metal layer such as an aluminum (Al), tungsten (w), or titanium (Ti) deposition layer. The etching stop layer 110 can also be a nonmetal layer such as polymer formed by deposition. The thickness of the etching stop layer 110 is about 1000˜3000 angstroms.

In FIG. 1, a buffer layer 120 is formed on the etching stop layer 110. The buffer layer 120 may be transparent SiO₂ formed by deposition, and the thickness of the buffer layer 120 is about 500˜1000 angstroms.

In FIG. 1, using photolithography, a semiconductor layer 130 is formed on part of the buffer layer 120. The semiconductor layer 130 may be a silicon (Si) layer formed by deposition, and the thickness of the semiconductor layer 130 is about 500˜1000 angstroms. Additionally, the semiconductor layer 130 serves as a channel layer of the TFT.

In FIG. 2, a gate oxide layer 210 is formed on the semiconductor layer 130 and the buffer layer 120. The gate oxide layer 210 may be a SiO₂ layer formed by deposition. Moreover, the gate oxide layer 210 can be smoothed by planarization.

In FIG. 2, using photolithography, agate layer 220 is formed on part of the gate oxide layer 210 located on the semiconductor layer 130. The gate layer 220 maybe a polysilicon layer, a metal layer or an alloy layer formed by deposition. Then, using an ion implantation process, a source region 230 and a drain region 240 are formed in the semiconductor layer 130 on either side of the gate layer 220. Thus, the TFT structure is formed. Moreover, it is possible to form an LDD (lightly doped drain) structure in the source/drain region 230, 240. In order to simplify the illustration, the conventional LDD structure is not shown in FIGS. 2˜8, but is not intended to limit the present invention. It is important to note that, because the TFT structure is formed over glass in the above steps, the present invention is not affected by the process temperature of the TFT.

In FIG. 2, using photolithography, a transparent electrode layer 250 is formed on part of the gate oxide layer 250. The transparent electrode layer 250 may be an indium tin oxide (ITO) layer formed by deposition.

In FIG. 3, a dielectric layer 310 is formed on the gate layer 230, the transparent electrode layer 250 and the gate oxide layer 210. The dielectric layer 310 may be a SiO₂ layer formed by deposition. Moreover, the dielectric layer 310 can be smoothed by planarization.

In FIG. 3, part of the dielectric layer 310 and the gate oxide layer 210 are removed to form a first opening hole 320, a second opening hole 330 and a third opening hole 340. The first opening hole 320 exposes partial surface of the transparent electrode 250, the second opening hole 330 exposes partial surface of the drain region 240 and the third opening hole 340 exposes partial surface of the source region 230. Then, a conductive material such as tungsten (w), titanium (Ti) or aluminum (Al) is filled in the first opening hole 320, the second opening hole 330 and the third opening hole 340 to form a first plug 350, a second plug 360 and a third plug 370.

In FIG. 3, using photolithography, a first conductive layer 380 and a second conductive layer 390 are formed on part of the dielectric layer 310. The first conductive layer 380 and the second conductive layer 390 may be a metal layer or an alloy layer formed by deposition. The first conductive layer 380 electrically connects the first plug 350 and the second plug 360, so that the drain region 240 electrically connects the transparent electrode 250. The second conductive layer 390 electrically connects the third plug 370, so that the source region 230 electrically connects the second conductive layer 390.

In FIG. 4, a passivation layer 410 is formed on the first conductive layer 380, the second conductive layer 390 and the dielectric layer 310. The passivation layer 410 may be a SiN layer, SiO₂ layer, PSG (phosphosilicate glass) layer or BPSG (borophosphosilicate glass) layer formed by deposition. Moreover, the passivation layer 410 can be smoothed by planarization. In addition, after a plurality of the TFT structures are formed, a cutting process can be further performed to separate the TFT structures.

In FIG. 5, using bonding, a plastic layer 510 is connected to the passivation layer 410. The plastic layer 510 is a transparent sheet made of PET, PC, epoxy or the like. The bonding can use direct bonding, anode bonding, low temperature bonding, intermediate layer bonding or adhesive bonding.

In FIG. 6, using polishing or etching, the glass substrate 100 is removed. The polishing may be CMP, and the etching may be wet etching which uses BOE (buffer oxide etcher).

In FIG. 7, using polishing or etching, the etching stop layer 110 is removed. The polishing may be CMP, and the etching may be wet etching.

In FIG. 8, using photolithography and etching, part of the buffer layer 120 and part of the gate oxide layer 210 are removed to form an opening hole 810. The opening hole 810 exposes the bottom surface of the transparent electrode 250. Thus, a TFT included plastic substrate is obtained.

Thus, the present invention can transfer the TFT structure from the glass layer to the plastic layer without damage from the process temperature of the TFT in the producing process, thereby improving device reliability, raising performance, and ameliorating the disadvantages of the prior art. Additionally, since the TFT structures can be separated before the formation of the plastic layer, the present invention creates no difficulties in cutting the plastic sheet.

Finally, while the invention has been described by way of example and in terms of the above, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of forming a thin film transistor (TFT) on a plastic sheet, comprising steps of:
(a) providing a glass substrate;
(b) forming an etching stop layer on the glass substrate;
(c) forming a buffer layer on the etching stop layer;
(d) forming at least one TFT structure on part of the buffer layer;
(e) forming a passivation layer on the TFT structure and the buffer layer;
(f) forming a plastic layer on the passivation layer; and
(g) removing the glass substrate and the etching stop layer.

2. The method according to claim 1, when a plurality of the TFT structures are formed, further comprising, after step (e), performing a cutting process to separate the TFT structures.

3. The method according to claim 1, wherein the etching stop layer is a metal layer formed by deposition.

4. The method according to claim 3, wherein the metal layer is an aluminum (Al) layer, a tungsten (W) layer or a titanium (Ti) layer.

5. The method according to claim 1, wherein the etching stop layer is a nonmetal layer formed by deposition.

6. The method according to claim 1, wherein the buffer layer is transparent.

7. The method according to claim 6, wherein the buffer layer is a SiO₂ layer formed by deposition.

8. The method according to claim 1, wherein the passivation layer is a SiO₂ layer formed by deposition.

9. The method according to claim 1, wherein the plastic layer is transparent.

10. The method according to claim 1, wherein the method of forming the plastic layer on the passivation layer comprises a bonding.

11. A method of forming a thin film transistor (TFT) on a plastic sheet, comprising steps of:
(a) providing a glass substrate;
(b) forming an etching stop layer on the glass substrate;
(c) forming a buffer layer on the etching stop layer;
(d) forming a semiconductor layer on part of the buffer layer;
(e) forming a gate oxide layer on the semiconductor layer and the buffer layer;
(f) forming a gate layer on part of the gate oxide layer located on the semiconductor layer;
(g) forming a source region and a drain region in the semiconductor layer on either side of the gate layer;
(h) forming a transparent electrode layer on part of the gate oxide layer;
(i) forming a dielectric layer on the gate layer, the transparent electrode layer and the gate oxide layer;
(j) forming a first opening hole, a second opening hole and a third opening hole through the dielectric layer and the gate oxide layer, wherein the first opening hole exposes partial surface of the transparent electrode, the second opening hole exposes partial surface of the drain region and the third opening hole exposes partial surface of the source region;
(k) filling conductive material in the first opening hole, the second opening hole and the third opening hole to form a first plug, a second plug and a third plug;
(l) forming a first conductive layer and a second conductive layer on part of the dielectric layer, wherein the first conductive layer connects the first plug and the second plug, and the second conductive layer connects the third plug;
(m) forming a passivation layer on the first conductive layer, the second conductive layer and the dielectric layer;
(n) forming a plastic layer on the passivation layer;
(o) removing the glass substrate;
(p) removing the etching stop layer; and
(q) removing part of the buffer layer and part of the gate oxide layer to expose the bottom surface of the transparent electrode.

12. The method according to claim 11, wherein the etching stop layer is a metal layer formed by deposition.

13. The method according to claim 11, wherein the etching stop layer is a nonmetal layer formed by deposition.

14. The method according to claim 11, wherein the buffer layer is transparent.

15. The method according to claim 14, wherein the buffer layer is a SiO₂ layer formed by deposition.

16. The method according to claim 11, wherein the transparent electrode is an indium tin oxide (ITO) layer formed by deposition.

17. The method according to claim 11, wherein the passivation layer is a SiO₂ layer formed by deposition.

18. The method according to claim 11, wherein the plastic layer is transparent.

19. The method according to claim 11, wherein the method of forming the plastic layer on the passivation layer comprises a bonding.

20. The method according to claim 11, wherein the source/drain region includes an LDD (lightly doped drain) structure.
